(19) United States
(12) Patent Application Publication
(10) Pub. No.: US 2025/0081480 A1
(43) Pub. Date: Mar. 6, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Jhih-Bin CHEN, Hsinchu (TW); Wan-Chen CHEN, Hsinchu (TW)

(73) Assignee: Taiwan Semiconductor Manufacturing Company, Ltd., Hsinchu (TW)

(21) Appl. No.: 18/242,867

(22) Filed: Sep. 6, 2023

(51) Int. Cl. H01L 21/306

(52) U.S. Cl. CPC H10D 1/696; H01L 21/30604

(57) ABSTRACT

A semiconductor device and a manufacturing method thereof are provided. The semiconductor device includes a top electrode layer, a bottom electrode layer, an insulator layer and a hard mask layer. The insulator layer is disposed between the top electrode layer and the bottom electrode. The top electrode layer, the insulator layer and the bottom electrode layer form a metal-insulator-metal structure. The hard mask layer stacks on the top electrode layer. The insulator layer protrudes from a first sidewall of the top electrode layer and a second sidewall of the bottom electrode layer.

### BACKGROUND

The disclosure relates in general to a semiconductor device and a manufacturing method thereof, and more particularly to a semiconductor device having a metal-insulator-metal (MIM) structure and a manufacturing method thereof.

Along with the development of the semiconductor technology, various semiconductor devices are invented. A semiconductor device having the MIM structure may be used to be a memory or a capacitor.

Two metal layers and one insulator layer in the semiconductor structure may be etched in one etching process to form the MIM structure. However, when etching metal layers, the metal may be deposited on the sidewall of the insulator layer and form a leakage path connecting the two metal layers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a semiconductor device according to one embodiment.

FIG. 2 shows a manufacturing method of the semiconductor device according to one embodiment.

FIG. 3 illustrates the details steps for etching the metal-insulator-metal structure.

FIG. 4 illustrates the detail features of the semiconductor device.

FIG. 5 shows a semiconductor device according to another embodiment.

FIG. 6 shows a manufacturing method of the semiconductor device according to one embodiment.

FIG. 7 illustrates the details steps for etching the metal-insulator-metal structure.

FIG. 8 illustrates the detail features of the semiconductor device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

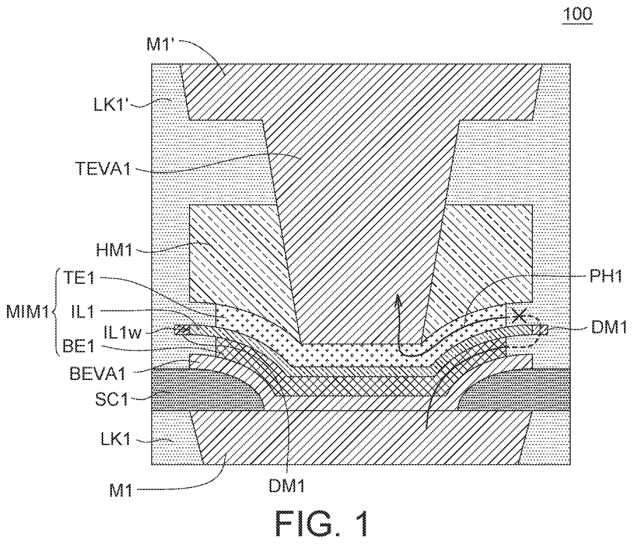

Please refer to FIG. 1, which shows a semiconductor device 100 according to one embodiment. The semiconductor device 100 includes a metal-insulator-metal (MIM) structure MIM1. The metal-insulator-metal structure MIM1 includes a top electrode layer TE1, an insulator layer IL1 and a bottom electrode layer BE1. The metal-insulator-metal structure MIM1 may be used to be a Resistive Random Access Memory (RRAM), a Magneto-resistive Random Access Memory (MRAM), a Conductive Bridge Memories (CBRAM), a Ferroelectric Random Access Memory (FeRAM) or a MIM capacitor.

The metal-insulator-metal structure MIM1 have been widely used in functional circuits such as mixed signal circuits, analog circuits, Radio Frequency (RF) circuits, Dynamic Random Access Memories (DRAMs), embedded DRAMs, and logic operation circuits. In system-on-chip (SOC) applications, different memory cells and capacitors for different functional circuits have to be integrated on a same chip to serve different purposes. For example, in mixed-signal circuits, capacitors are used as decoupling capacitors and high-frequency noise filters. For DRAM and embedded DRAM circuits, capacitors are used for memory storage, while for RF circuits, capacitors are used in oscillators and phase-shift networks for coupling and/or bypassing purposes. For microprocessors, capacitors are used for decoupling. As its name suggests, an MIM capacitor includes a sandwich structure of interleaving metal layers and insulator layers. An example MIM capacitor includes a plurality of conductor plate layers, each of which is insulated from an adjacent conductor plate layer by an insulator layer. As an MIM capacitor is fabricated in a BEOL structure to have a larger surface area, its conductor plate layers extend over multiple underlying top metal contact features that are connected to logic or control circuitry.

As shown in FIG. 1, the semiconductor device 100 includes a metal layer M1 and a metal layer M1′. The metal-insulator-metal structure MIM1 is formed between the metal layer M1 and the metal layer M1′. A top electrode via TEVA1 is formed between the metal layer M1′ and the metal-insulator-metal structure MIM1 to connect the metal layer M1′ and the metal-insulator-metal structure MIM1. A bottom electrode via BEVA1 is formed between the metal-insulator-metal structure MIM1 and the metal layer M1 to connect the metal-insulator-metal structure MIM1 and the metal layer M1. The hard mask layer HM1 covers the metal-insulator-metal structure MIM1 to protect the metal-insulator-metal structure MIM1. To pattern the metal-insulator-metal structure MIM1, the hard mask layer HM1, the metal-insulator-metal structure MIM1 and the bottom electrode via BEVA1 are etched through one etching process. The metal may be splashed to form a re-deposit metal DM1 at a sidewall IL1w of the insulator layer IL1. In this embodiment, the top electrode layer TEL and the bottom electrode layer BE1 are retracted. Even if the re-deposit metal DM1 is formed at the sidewall IL1w of the insulator layer IL1, the leakage path PH1 is broken and would not damage the insulation between the top electrode layer TEL and the bottom electrode layer BE1.

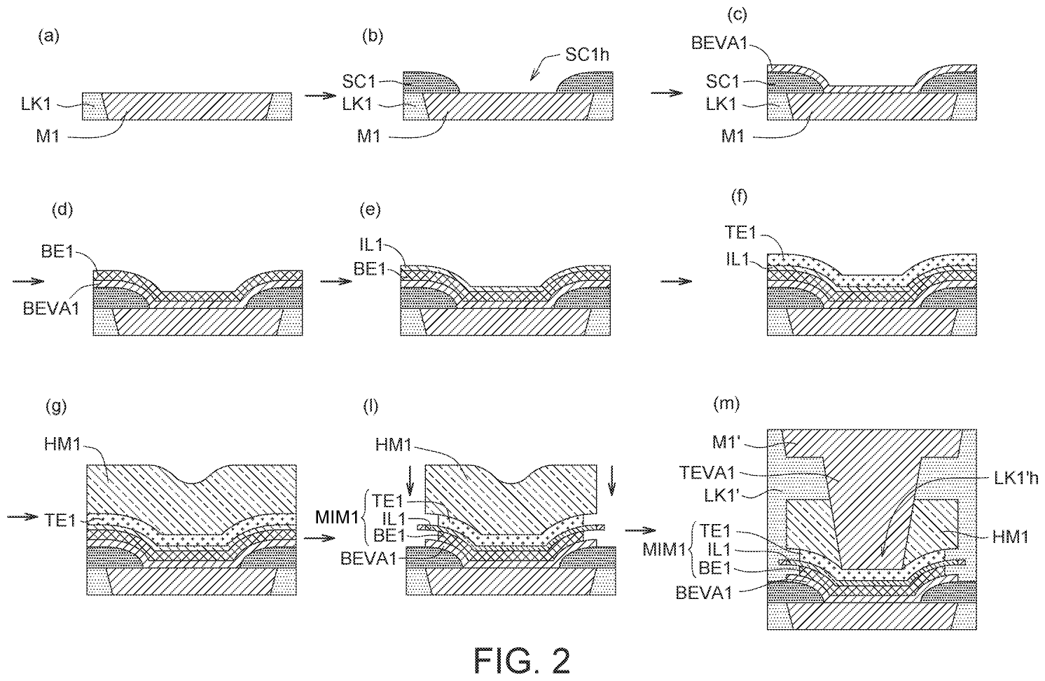

Please refer to FIG. 2, which shows a manufacturing method of the semiconductor device 100 according to one embodiment. As shown in the drawing (a) of FIG. 2, the metal layer M1 is formed. The metal layer M1 may be located within a low-k material LK1, and the top of the metal layer M1 is exposed. The material of the metal layer M1 is, for example, Tungsten (W), copper (Cu), aluminum (Al), Cobalt (Co), Ruthenium (Ru), Molybdenum (Mo), Tantalum (Ta), Titanium (Ti), alloys thereof, and/or combinations thereof. The material of the low-k material LK1 is, for example, silicon oxide, phosphosilicate glass (PSG), borosilicate glass (BSG), boron-doped phosphosilicate glass (BPSG), or the like; a nitride such as silicon nitride; combinations thereof. The low-k material LK1 has, for example, a k-value of less than 2.5.

Then, as shown in the drawing (b) of FIG. 2, a silicon carbide layer SC1 having a concave SC1h is formed. The concave SC1h exposes the top of the metal layer M1.

Afterwards, as shown in the drawing (c) of FIG. 2, the bottom electrode via BEVA1 is formed on the silicon carbide layer SC1 and part of the metal layer M1. The bottom electrode via BEVA1 is electrically connected to the metal layer M1. The material of the bottom electrode via BEVA1 is, for example, Tungsten (W), copper (Cu), aluminum (Al), Cobalt (Co), Ruthenium (Ru), Molybdenum (Mo), Tantalum (Ta), Titanium (Ti), alloys thereof, and/or combinations thereof. In some embodiments, the metal layer M1 and the bottom electrode via BEVA1 may have the same material.

Next, as shown in the drawing (d) of FIG. 2, the bottom electrode layer BE1 is formed on the bottom electrode via BEVA1. The bottom electrode layer BE1 is electrically connected to the bottom electrode via BEVA1. The material of the bottom electrode layer BE1 is, for example, platinum (Pt), aluminum copper (AlCu), titanium nitride (TiN), gold (Au), titanium (Ti), tantalum (Ta), tantalum nitride (TaN), tungsten (W), tungsten nitride (WN), or copper (Cu) and/or combinations thereof.

Afterwards, as shown in the drawing (e) of FIG. 2, the insulator layer IL1 is formed on the bottom electrode layer BE1. The material of the insulator layer IL1 is, for example, high-k dielectric material, such as hafnium dioxide (HfO₂), zirconium dioxide (ZrO₂), aluminum oxide (Al₂O₃), tantalum pentoxide (Ta₂O₅), hafnium aluminum oxide (HfAlO), hafnium zirconium oxide (HfZrO), nickel oxide (NiO), titanium oxide (TiO), hafnium oxide (HfO), zirconium oxide (ZrO), zinc oxide (ZnO), tungsten oxide (WO₃), aluminum oxide (Al₂O₃), tantalum oxide (TaO), molybdenum oxide (MoO), or copper oxide (CuO), or the like.

Next, as shown in the drawing (f) of FIG. 2, the top electrode layer TE1 is formed on the insulator layer IL1. The material of the top electrode layer TE1 is, for example, platinum (Pt), aluminum copper (AlCu), titanium nitride (TiN), gold (Au), titanium (Ti), tantalum (Ta), tantalum nitride (TaN), tungsten (W), tungsten nitride (WN), or copper (Cu) and/or combinations thereof.

Then, as shown in the drawing (g) of FIG. 2, the hard mask layer HM1 is form on the top electrode layer TE1. The material of the hard mask layer HM1 is, for example, buried oxide (BOX) layer, a silicon oxide layer, or the like.

Afterwards, as shown in the drawing (l) of FIG. 2, the hard mask layer HM1, the top electrode layer TE1, the insulator layer IL1, the bottom electrode layer BE1 and the bottom electrode via BEVA1 are etched sequentially. In this embodiment, the hard mask layer HM1, the top electrode layer TE1, the insulator layer IL1, the bottom electrode layer BE1 and the bottom electrode via BEVA1 are etched in one etching process. For example, the hard mask layer HM1, the top electrode layer TE1, the insulator layer IL1, the bottom electrode layer BE1 and the bottom electrode via BEVA1 are etched in the same chamber with different parameters.

Then, as shown in the drawing (m) of FIG. 2, the low-k material LK1′ with a concave LK1′h is disposed on the hard mask layer HM1, the metal-insulator-metal structure MIM1 and the bottom electrode via BEVA1, the top electrode via TEVA1 is formed in a concave LK1′h, and the metal layer M1′ is formed on the top electrode via TEVA1 and the low-k material LK1′.

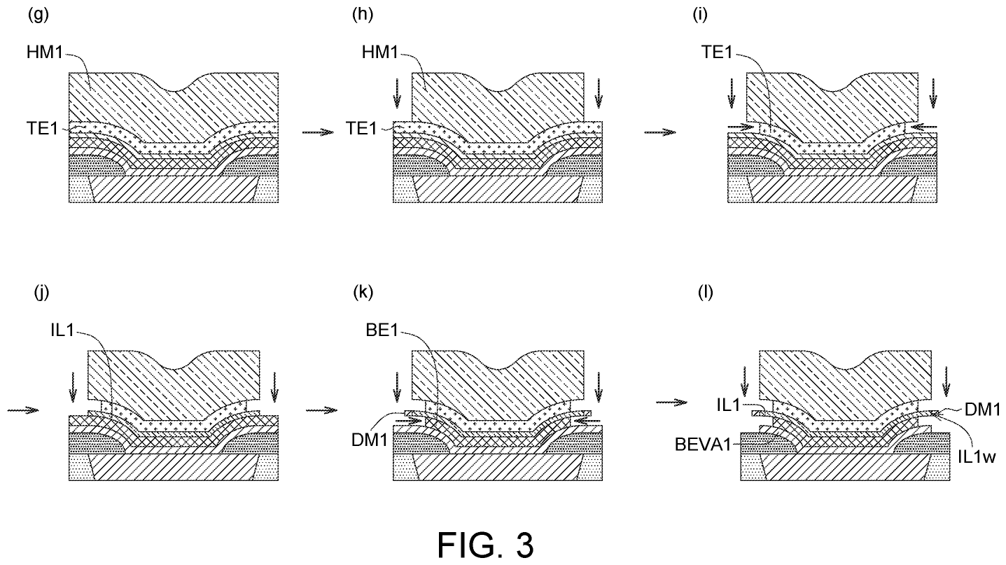

Please refer to FIG. 3, which illustrates the details steps for etching the metal-insulator-metal structure MIM1. The one step etching process is shown in the drawing (g) to the drawing (l) of FIG. 3. From the drawing (g) to the drawing (l) of FIG. 3, the hard mask layer HM1, the top electrode layer TE1, the insulator layer IL1, the bottom electrode layer BE1 and the bottom electrode via BEVA1 are etched in same chamber with different parameters. In this chamber, the parameters can be controlled to adjust the degree of the chemical etching and the degree of the physical etching.

As shown in the drawing (h) of FIG. 3, the hard mask layer HM1 is mainly etched through a vertical etching step. For example, the hard mask layer HM1 is mainly etched through a physical etching step which is an isotropic etching step.

As shown in the drawing (i) of FIG. 3, the top electrode layer TE1 is etched through a lateral-and-vertical etching step. For example, the top electrode layer TE1 is etched through a chemical-and-physical etching step which is an anisotropic-and-isotropic etching step. Therefore, the top electrode layer TE1 is retracted.

As shown in the drawing (j) of FIG. 3, the insulator layer IL1 is mainly etched through a vertical etching step. For example, the insulator layer IL1 is mainly etched through a physical etching step which is an isotropic etching step. Therefore, the insulator layer IL1 is not retracted.

As show in the drawing (k) of FIG. 3, the bottom electrode layer BE1 is etched through a lateral-and-vertical etching step. For example, the bottom electrode layer BE1 is etched through a chemical-and-physical etching step which is an anisotropic-and-isotropic etching step. Therefore, the bottom electrode layer BE1 is retracted.

As shown in the drawing (l) of FIG. 3, the bottom electrode via BEVA1 is mainly etched through a vertical etching step. For example, the bottom electrode via BEVA1 is mainly etched through a physical etching step which is an isotropic etching step.

When etching the bottom electrode layer BE1 and the bottom electrode via BEVA1, the metal may be splashed to form the re-deposit metal DM1 at the sidewall IL1w of the insulator layer IL1. In this embodiment, the top electrode layer TEL and the bottom electrode layer BE1 are retracted. Even if the re-deposit metal DM1 is formed at the sidewall IL1w of the insulator layer IL1, the leakage path is broken and would not damage the insulation between the top electrode layer TE1 and the bottom electrode layer BE1.

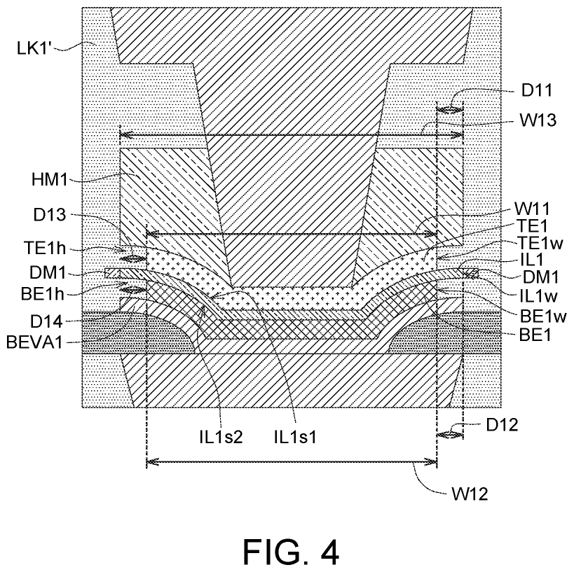

Please refer to FIG. 4, which illustrates the detail features of the semiconductor device 100. The insulator layer IL1 protrudes, for example, 5 to 500 Å beyond the first sidewall TE1w of the top electrode layer TE1. That is, the distance D11 between the first sidewall TE1w of the top electrode layer TE1 and the sidewall IL1w of the insulator layer IL1 is, for example, 5 to 500 Å.

The insulator layer IL1 protrudes, for example, 5 to 500 Å beyond the second sidewall BE1w of the bottom electrode layer BE1. That is, the distance D12 between the second sidewall BE1w of the bottom electrode layer BE1 and the sidewall IL1w of the insulator layer IL1 is, for example, 5 to 500 Å.

Moreover, the first sidewall TE1w of the top electrode layer TEL and the second sidewall BE1w of the bottom electrode layer BE1 are located inside of a projection of the insulator layer IL1.

Furthermore, the low-k material LK1′ is filled in a concave TE1h surrounded by the hard mask layer HM1, the insulator layer IL1 and the top electrode layer TE1. The concave TE1h is located below the hard mask layer HM1 and located above the insulator layer IL1. The depth D13 of the concave TE1h is, for example, 5 to 500 Å.

The low-k material LK1′ is filled in a concave BE1h surrounded by the bottom electrode layer BE1, the insulator layer IL1 and the bottom electrode via BEVA1. The concave BE1h is located below the insulator layer IL1 and located above the bottom electrode via BEVA1. The depth D14 of the concave BE1h is, for example, 5 to 500 Å.

Moreover, a top surface IL1s1 of the insulator layer IL1 is partially exposed by the top electrode layer TE1. A bottom surface IL1s2 of the insulator layer IL1 is partially exposed by the bottom electrode layer BE1.

Moreover, a width W13 of the insulator layer IL1 is larger than a width W11 of the top electrode layer TE1 and a width W12 of the bottom electrode layer BE1. The width W11 of the top electrode layer TE1 and the width W12 of the bottom electrode layer BE1 are substantially identical. Or, the width W11 of the top electrode layer TE1 and the width W12 of the bottom electrode layer BE1 are not identical.

According to the embodiment disclosed in FIGS. 1 to 4, the top electrode layer TE1 and the bottom electrode layer BE1 are retracted. Even if the re-deposit metal DM1 is formed at the sidewall IL1w of the insulator layer IL1, the leakage path is broken and would not damage the insulation between the top electrode layer TE1 and the bottom electrode layer BE1.

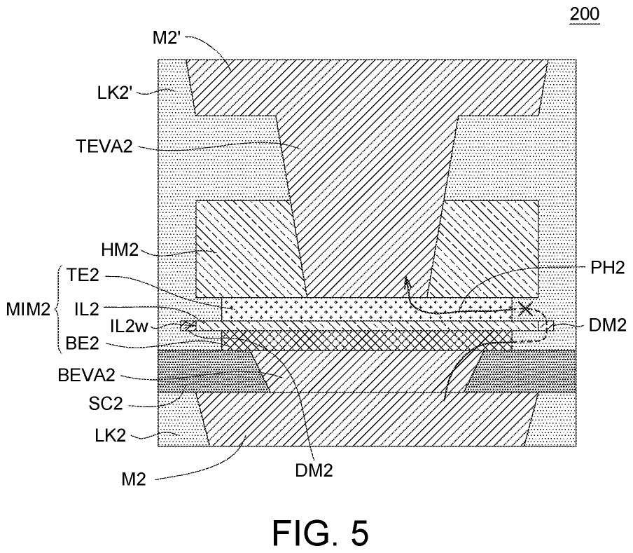

Please refer to FIG. 5, which shows a semiconductor device 200 according to another embodiment. The semiconductor device 200 includes a metal-insulator-metal (MIM) structure MIM2. The metal-insulator-metal structure MIM2 includes a top electrode layer TE2, an insulator layer IL2 and a bottom electrode layer BE2. The metal-insulator-metal structure MIM2 may be used to be a Resistive Random Access Memory (RRAM), a Magneto-resistive Random Access Memory (MRAM), a Conductive Bridge Memories (CBRAM), a Ferroelectric Random Access Memory (FeRAM) or a MIM capacitor.

The metal-insulator-metal structure MIM2 have been widely used in functional circuits such as mixed signal circuits, analog circuits, Radio Frequency (RF) circuits, Dynamic Random Access Memories (DRAMs), embedded DRAMs, and logic operation circuits. In system-on-chip (SOC) applications, different memory cells and capacitors for different functional circuits have to be integrated on a same chip to serve different purposes. For example, in mixed-signal circuits, capacitors are used as decoupling capacitors and high-frequency noise filters. For DRAM and embedded DRAM circuits, capacitors are used for memory storage, while for RF circuits, capacitors are used in oscillators and phase-shift networks for coupling and/or bypassing purposes. For microprocessors, capacitors are used for decoupling. As its name suggests, an MIM capacitor includes a sandwich structure of interleaving metal layers and insulator layers. An example MIM capacitor includes a plurality of conductor plate layers, each of which is insulated from an adjacent conductor plate layer by an insulator layer. As an MIM capacitor is fabricated in a BEOL structure to have a larger surface area, its conductor plate layers extend over multiple underlying top metal contact features that are connected to logic or control circuitry.

As shown in FIG. 5, the semiconductor device 200 includes a metal layer M2 and a metal layer M2′. The metal-insulator-metal structure MIM2 is formed between the metal layer M2 and the metal layer M2′. A top electrode via TEVA2 is formed between the metal layer M2′ and the metal-insulator-metal structure MIM2 to connect the metal layer M2′ and the metal-insulator-metal structure MIM2. A bottom electrode via BEVA2 is formed between the metal-insulator-metal structure MIM2 and the metal layer M2 to connect the metal-insulator-metal structure MIM2 and the metal layer M2. The hard mask layer HM2 covers the metal-insulator-metal structure MIM2 to protect the metal-insulator-metal structure MIM2. To pattern the metal-insulator-metal structure MIM2, the hard mask layer HM2 and the metal-insulator-metal structure MIM2 are etched through one etching process. The metal may be splashed to form a re-deposit metal DM2 at a sidewall IL2w of the insulator layer IL2. In this embodiment, the top electrode layer TE2 and the bottom electrode layer BE2 are retracted. Even if the re-deposit metal DM2 is formed at the sidewall IL2w of the insulator layer IL2, the leakage path PH2 is broken and would not damage the insulation between the top electrode layer TE2 and the bottom electrode layer BE2.

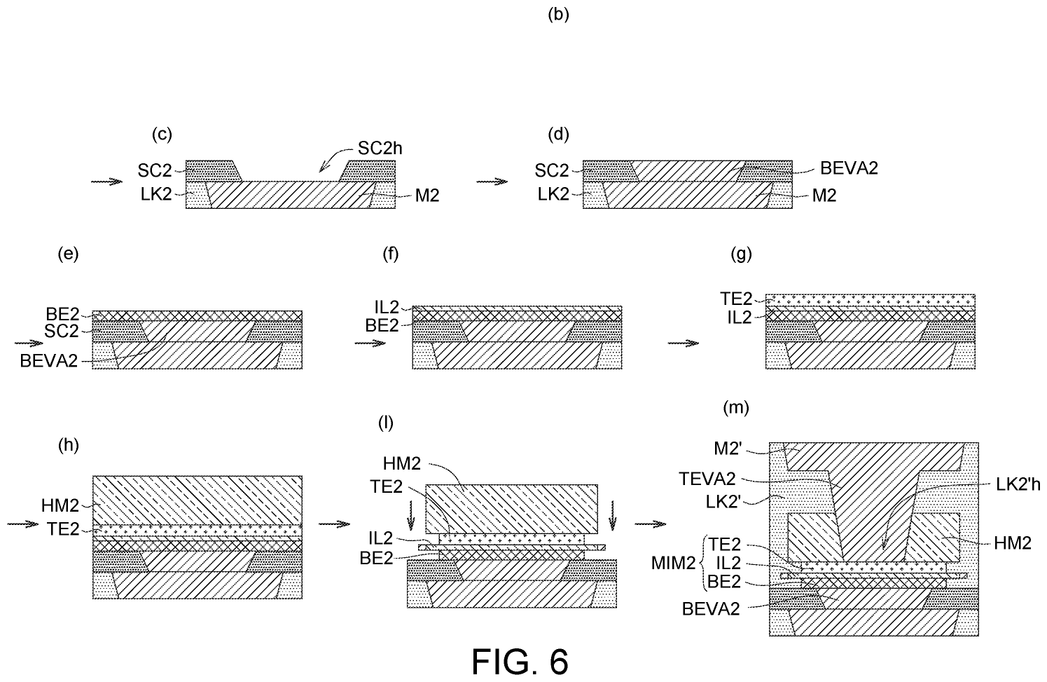

Please refer to FIG. 6, which shows a manufacturing method of the semiconductor device 200 according to one embodiment. As shown in the drawing (a) of FIG. 6, the metal layer M2 is formed. The metal layer M2 may be located within a low-k material LK2, and the top of the metal layer M2 is exposed. The material of the metal layer M2 is, for example, Tungsten (W), copper (Cu), aluminum (Al), Cobalt (Co), Ruthenium (Ru), Molybdenum (Mo), Tantalum (Ta), Titanium (Ti), alloys thereof, and/or combinations thereof. The material of the low-k material LK2 is, for example, silicon oxide, phosphosilicate glass (PSG), borosilicate glass (BSG), boron-doped phosphosilicate glass (BPSG), or the like; a nitride such as silicon nitride; combinations thereof. The low-k material LK2 has, for example, a k-value of less than 2.5.

Then, as shown in the drawing (b) of FIG. 6, a silicon carbide layer SC2 is formed on the low-k material LK2 and the metal layer M2.

Next, as shown in the drawing (c) of FIG. 6, a concave SC2h is formed in the silicon carbide layer SC2 to expose the top of the metal layer M2.

Afterwards, as shown in the drawing (d) of FIG. 6, a bottom electrode via BEVA2 is formed in the concave SC2h. The bottom electrode via BEVA2 is electrically connected to the metal layer M2. The material of the bottom electrode via BEVA2 is, for example, Tungsten (W), copper (Cu), aluminum (Al), Cobalt (Co), Ruthenium (Ru), Molybdenum (Mo), Tantalum (Ta), Titanium (Ti), alloys thereof, and/or combinations thereof. In some embodiments, the metal layer M2 and the bottom electrode via BEVA2 may have the same material.

Next, as shown in the drawing (e) of FIG. 6, the bottom electrode layer BE2 is formed on the bottom electrode via BEVA2 and the silicon carbide layer SC2. The bottom electrode layer BE2 is electrically connected to the bottom electrode via BEVA2. The material of the bottom electrode layer BE2 is, for example, platinum (Pt), aluminum copper (AlCu), titanium nitride (TiN), gold (Au), titanium (Ti), tantalum (Ta), tantalum nitride (TaN), tungsten (W), tungsten nitride (WN), or copper (Cu) and/or combinations thereof.

Afterwards, as shown in the drawing (f) of FIG. 6, the insulator layer IL2 is formed on the bottom electrode layer BE2. The material of the insulator layer IL2 is, for example, high-k dielectric material, such as hafnium dioxide (HfO₂), zirconium dioxide (ZrO₂), aluminum oxide (Al₂O₃), tantalum pentoxide (Ta₂O₅), hafnium aluminum oxide (HfAlO), hafnium zirconium oxide (HfZrO), nickel oxide (NiO), titanium oxide (TiO), hafnium oxide (HfO), zirconium oxide (ZrO), zinc oxide (ZnO), tungsten oxide (WO₃), aluminum oxide (Al₂O₃), tantalum oxide (TaO), molybdenum oxide (MoO), or copper oxide (CuO), or the like.

Next, as shown in the drawing (g) of FIG. 6, the top electrode layer TE2 is formed on the insulator layer IL2. The material of the top electrode layer TE2 is, for example, platinum (Pt), aluminum copper (AlCu), titanium nitride (TiN), gold (Au), titanium (Ti), tantalum (Ta), tantalum nitride (TaN), tungsten (W), tungsten nitride (WN), or copper (Cu) and/or combinations thereof.

Then, as shown in the drawing (h) of FIG. 6, the hard mask layer HM2 is form on the top electrode layer TE2. The material of the hard mask layer HM2 is, for example, buried oxide (BOX) layer, a silicon oxide layer, or the like.

Afterwards, as shown in the drawing (l) of FIG. 6, the hard mask layer HM2, the top electrode layer TE2, the insulator layer IL2 and the bottom electrode layer BE2 are etched sequentially. In this embodiment, the hard mask layer HM2, the top electrode layer TE2, the insulator layer IL2 and the bottom electrode layer BE2 are etched in one etching process. For example, the hard mask layer HM2, the top electrode layer TE2, the insulator layer IL2 and the bottom electrode layer BE2 are etched in the same chamber with different parameters.

Then, as shown in the drawing (m) of FIG. 6, the low-k material LK2′ with a concave LK2′h is disposed on the hard mask layer HM2, the metal-insulator-metal structure MIM2 and the silicon carbide layer SC2, the top electrode via TEVA2 is formed in a concave LK2′h, and the metal layer M2′ is formed on the top electrode via TEVA2 and the low-k material LK2′.

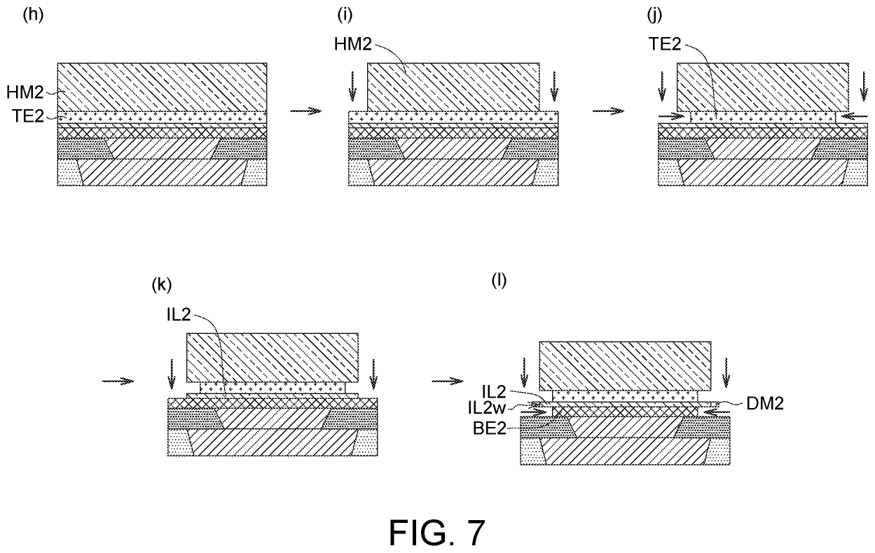

Please refer to FIG. 7, which illustrates the details steps for etching the metal-insulator-metal structure MIM2. The one step etching process is shown in the drawing (h) to the drawing (l) of FIG. 6. From the drawing (h) to the drawing (l) of FIG. 6, the hard mask layer HM2, the top electrode layer TE2, the insulator layer IL2 and the bottom electrode layer BE2 are etched in same chamber with different parameters. In this chamber, the parameters can be controlled to adjust the degree of the chemical etching and the degree of the physical etching.

As shown in the drawing (i) of FIG. 7, the hard mask layer HM2 is mainly etched through a vertical etching step. For example, the hard mask layer HM2 is mainly etched through a physical etching step which is an isotropic etching step.

As shown in the drawing (j) of FIG. 7, the top electrode layer TE2 is etched through a lateral-and-vertical etching step. For example, the top electrode layer TE2 is etched through a chemical-and-physical etching step which is an anisotropic-and-isotropic etching step. Therefore the top electrode layer TE2 is retracted.

As shown in the drawing (k) of FIG. 7, the insulator layer IL2 is mainly etched through a vertical etching step. For example, the insulator layer IL2 is mainly etched through a physical etching step which is an isotropic etching step. Therefore, the insulator layer IL2 is not retracted.

As show in the drawing (l) of FIG. 7, the bottom electrode layer BE2 is etched through a lateral-and-vertical etching step. For example, the bottom electrode layer BE2 is etched through a chemical-and-physical etching step which is an anisotropic-and-isotropic etching step. Therefore, the bottom electrode layer BE2 is retracted.

When etching the bottom electrode layer BE2, the metal may be splashed to form the re-deposit metal DM2 at the sidewall IL2w of the insulator layer IL2. In this embodiment, the top electrode layer TE2 and the bottom electrode layer BE2 are retracted. Even if the re-deposit metal DM2 is formed at the sidewall IL2w of the insulator layer IL2, the leakage path is broken and would not damage the insulation between the top electrode layer TE2 and the bottom electrode layer BE2.

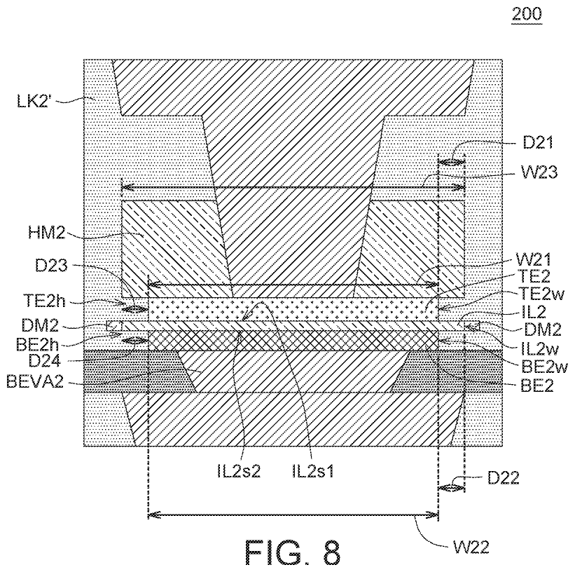

Please refer to FIG. 8, which illustrates the detail features of the semiconductor device 200. The insulator layer IL2 protrudes, for example, 5 to 500 Å beyond the first sidewall TE2w of the top electrode layer TE2. That is, the distance D21 between the first sidewall TE2w of the top electrode layer TE2 and the sidewall IL2w of the insulator layer IL2 is, for example, 5 to 500 Å.

The insulator layer IL2 protrudes, for example, 5 to 500 Å beyond the second sidewall BE2w of the bottom electrode layer BE2. That is, the distance D22 between the second sidewall BE2w of the bottom electrode layer BE2 and the sidewall IL2w of the insulator layer IL2 is, for example, 5 to 500 Å.

Moreover, the first sidewall TE2w of the top electrode layer TE2 and the second sidewall BE2w of the bottom electrode layer BE2 are located inside of a projection of the insulator layer IL2.

Furthermore, the low-k material LK2′ is filled in a concave TE2h surrounded by the hard mask layer HM2, the insulator layer IL2 and the top electrode layer TE2. The concave TE2h is located below the hard mask layer HM2 and located above the insulator layer IL2. The depth D23 of the concave TE2h is, for example, 5 to 500 Å.

The low-k material LK2′ is filled in a concave BE2h surrounded by the bottom electrode layer BE2, the insulator layer IL2 and the silicon carbide layer SC2. The concave BE2h is located below the insulator layer IL2 and located above the silicon carbide layer SC2. The depth D24 of the concave BE2h is, for example, 5 to 500 Å.

Moreover, a top surface IL2s1 of the insulator layer IL2 is partially exposed by the top electrode layer TE2. A bottom surface IL2s2 of the insulator layer IL2 is partially exposed by the bottom electrode layer BE2.

Moreover, a width W23 of the insulator layer IL2 is larger than a width W21 of the top electrode layer TE2 and a width W22 of the bottom electrode layer BE2. The width W21 of the top electrode layer TE2 and the width W22 of the bottom electrode layer BE2 are substantially identical. Or, the width W21 of the top electrode layer TE2 and the width W22 of the bottom electrode layer BE2 are not identical.

According to the embodiment disclosed in FIGS. 5 to 8, the top electrode layer TE2 and the bottom electrode layer BE2 are retracted. Even if the re-deposit metal DM2 is formed at the sidewall IL2w of the insulator layer IL2, the leakage path is broken and would not damage the insulation between the top electrode layer TE2 and the bottom electrode layer BE2.

Example Embodiment A: A semiconductor device is provided. The semiconductor device includes a top electrode layer, a bottom electrode layer, an insulator layer and a hard mask layer. The insulator layer is disposed between the top electrode layer and the bottom electrode. The top electrode layer, the insulator layer and the bottom electrode layer form a metal-insulator-metal structure. The hard mask layer stacks on the top electrode layer. The insulator layer protrudes from a first sidewall of the top electrode layer and a second sidewall of the bottom electrode layer.

Another Example Embodiment based on the Example Embodiment A: The insulator layer protrudes 5 to 500 Å beyond the first sidewall of the top electrode layer.

Another Example Embodiment based on the Example Embodiment A: The insulator layer protrudes 5 to 500 Å beyond the second sidewall of the bottom electrode layer.

Another Example Embodiment based on the Example Embodiment A: A low-k material is filled in a concave surrounded by the hard mask layer, the insulator layer and the top electrode layer.

Another Example Embodiment based on the Example Embodiment A: A low-k material is filled in a concave surrounded by the bottom electrode layer, the insulator layer and a bottom electrode via.

Another Example Embodiment based on the Example Embodiment A: A bottom surface of the insulator layer is partially exposed by the bottom electrode layer.

Another Example Embodiment based on the Example Embodiment A: A top surface of the insulator layer is partially exposed by the top electrode layer.

Another Example Embodiment based on the Example Embodiment A: A width of the insulator layer is larger than a width of the top electrode layer and a width of the bottom electrode layer.

Example Embodiment B: A manufacturing method of a semiconductor device. The manufacturing method of the semiconductor device includes the following steps. A bottom electrode layer is formed. An insulator layer is formed on the bottom electrode layer. A top electrode layer is formed on the insulator layer. The top electrode layer, the insulator layer and the bottom electrode layer form a metal-insulator-metal structure. A hard mask layer is formed on the top electrode layer. The hard mask layer, the top electrode layer, the insulator layer and the bottom electrode layer are sequentially etched. The top electrode layer is etched through a lateral-and-vertical etching step. The insulator layer is etched through a vertical etching step. The bottom electrode layer is etched through a lateral-and-vertical etching step.

Another Example Embodiment based on the Example Embodiment B: The top electrode layer is etched through a chemical-and-physical etching step, the insulator layer is etched through a physical etching step, and the bottom electrode layer is etched through a chemical-and-physical etching step.

Another Example Embodiment based on the Example Embodiment B: The hard mask layer is etched through a vertical etching step.

Another Example Embodiment based on the Example Embodiment B: The hard mask layer, the top electrode layer, the insulator layer and the bottom electrode layer are etched in same chamber with different parameters.

Another Example Embodiment based on the Example Embodiment B: Part of the top electrode layer located above the insulator layer is removed via the lateral-and-vertical etching step.

Another Example Embodiment based on the Example Embodiment B: Part of the bottom electrode layer located below the insulator layer is removed via the lateral-and-vertical etching step.

Example embodiment C: A semiconductor device is provided. The semiconductor device includes a top electrode layer, a bottom electrode layer, an insulator layer and a hard mask layer. The insulator layer is disposed between the top electrode layer and the bottom electrode layer. The top electrode layer, the insulator layer and the bottom electrode layer form a metal-insulator-metal structure. The hard mask layer is stacked on the top electrode layer. A first sidewall of the top electrode layer and a second sidewall of the bottom electrode layer are located inside of a projection of the insulator layer.

Another Example Embodiment based on the Example Embodiment C: A low-k material is filled in a concave surrounded by the hard mask layer, the insulator layer and the top electrode layer.

Another Example Embodiment based on the Example Embodiment C: A low-k material is filled in a concave surrounded by the bottom electrode layer, the insulator layer and a bottom electrode via.

Another Example Embodiment based on the Example Embodiment: C A bottom surface of the insulator layer is partially exposed by the bottom electrode layer.

Another Example Embodiment based on the Example Embodiment C: A top surface of the insulator layer is partially exposed by the top electrode layer.

Another Example Embodiment based on the Example Embodiment C: A width of the insulator layer is larger than a width of the top electrode layer and a width of the bottom electrode layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a top electrode layer;
a bottom electrode layer;
an insulator layer, disposed between the top electrode layer and the bottom electrode, wherein the top electrode layer, the insulator layer and the bottom electrode layer form a metal-insulator-metal structure; and
a hard mask layer, stacked on the top electrode layer;
wherein the insulator layer protrudes from a first sidewall of the top electrode layer and a second sidewall of the bottom electrode layer.

2. The semiconductor device according to claim 1, wherein the insulator layer protrudes 5 to 500 Å beyond the first sidewall of the top electrode layer.

3. The semiconductor device according to claim 1, wherein the insulator layer protrudes 5 to 500 Å beyond the second sidewall of the bottom electrode layer.

4. The semiconductor device according to claim 1, wherein a low-k material is filled in a concave surrounded by the hard mask layer, the insulator layer and the top electrode layer.

5. The semiconductor device according to claim 1, wherein a low-k material is filled in a concave surrounded by the bottom electrode layer, the insulator layer and a bottom electrode via.

6. The semiconductor device according to claim 1, wherein a bottom surface of the insulator layer is partially exposed by the bottom electrode layer.

7. The semiconductor device according to claim 1, wherein a top surface of the insulator layer is partially exposed by the top electrode layer.

8. The semiconductor device according to claim 1, wherein a width of the insulator layer is larger than a width of the top electrode layer and a width of the bottom electrode layer.

9. A manufacturing method of a semiconductor device, comprising:
forming a bottom electrode layer;
forming an insulator layer on the bottom electrode layer;
forming a top electrode layer on the insulator layer, wherein the top electrode layer, the insulator layer and the bottom electrode layer form a metal-insulator-metal structure;
forming a hard mask layer on the top electrode layer; and
sequentially etching the hard mask layer, the top electrode layer, the insulator layer and the bottom electrode layer;
wherein the top electrode layer is etched through a lateral-and-vertical etching step, the insulator layer is etched through a vertical etching step, and the bottom electrode layer is etched through a lateral-and-vertical etching step.

10. The manufacturing method of the semiconductor device according to claim 9, wherein the top electrode layer is etched through a chemical-and-physical etching step, the insulator layer is etched through a physical etching step, and the bottom electrode layer is etched through a chemical-and-physical etching step.

11. The manufacturing method of the semiconductor device according to claim 9, wherein the hard mask layer is etched through a vertical etching step.

12. The manufacturing method of the semiconductor device according to claim 9, wherein the hard mask layer, the top electrode layer, the insulator layer and the bottom electrode layer are etched in same chamber with different parameters.

13. The manufacturing method of the semiconductor device according to claim 9, wherein part of the top electrode layer located above the insulator layer is removed via the lateral-and-vertical etching step.

14. The manufacturing method of the semiconductor device according to claim 9, wherein part of the bottom electrode layer located below the insulator layer is removed via the lateral-and-vertical etching step.

15. A semiconductor device, comprising:
a top electrode layer;
a bottom electrode layer;
an insulator layer, disposed between the top electrode layer and the bottom electrode layer, wherein the top electrode layer, the insulator layer and the bottom electrode layer form a metal-insulator-metal structure; and
a hard mask layer, stacked on the top electrode layer;
wherein a first sidewall of the top electrode layer and a second sidewall of the bottom electrode layer are located inside of a projection of the insulator layer.

16. The semiconductor device according to claim 15, wherein a low-k material is filled in a concave surrounded by the hard mask layer, the insulator layer and the top electrode layer.

17. The semiconductor device according to claim 15, wherein a low-k material is filled in a concave surrounded by the bottom electrode layer, the insulator layer and a bottom electrode via.

18. The semiconductor device according to claim 15, wherein a bottom surface of the insulator layer is partially exposed by the bottom electrode layer.

19. The semiconductor device according to claim 15, wherein a top surface of the insulator layer is partially exposed by the top electrode layer.

20. The semiconductor device according to claim 15, wherein a width of the insulator layer is larger than a width of the top electrode layer and a width of the bottom electrode layer.
